(19) United States
(12) Patent Application Publication
(10) Pub. No.: US 2026/0293493 A1
(43) Pub. Date: Sep. 24, 2026

(54) ELECTRONIC DEVICE AND METHOD FOR MANUFACTURING THE SAME

(71) Applicant: Samsung Display Co., LTD., Yongin-si (KR)

(72) Inventors: KYONGBIN JIN, Yongin-si (KR); JongIn RYU, Yongin-si (KR); JIYEON LEE, Yongin-si (KR); HYORIN LEE, Yongin-si (KR)

(21) Appl. No.: 19/562,095

(22) Filed: Mar. 10, 2026

(30) Foreign Application Priority Data
Mar. 19, 2025 (KR) 10-2025-0035180

(51) Int. Cl. H10K 59/80; H10K 59/12; H10K 59/65; H10K 102/00

(52) U.S. Cl. CPC H10K 59/8722; H10K 59/1201; H10K 59/65; H10K 59/8792; H10K 2102/351

(57) ABSTRACT

An electronic device includes a display module that displays an image and detects an external input, a window disposed on the display module, defined an opening, and including a first region surrounding the opening and a second region spaced apart from the opening in a plan view, an anti-fingerprint layer disposed on the second region of the window, an adhesive layer disposed on the first region of the window, and an electronic module disposed on the adhesive layer, overlapping the opening, and at least partially accommodated in the opening. The first region is disposed between the opening and the second region in the plan view.

This application claims priority to Korean Patent Application No. 10-2025-0035180, filed on Mar. 19, 2025, and all the benefits accruing therefrom under 35 U.S.C. §119, the content of which in its entirety is herein incorporated by reference.

### BACKGROUND

### 1. Field

The disclosure herein relates to an electronic device with improved reliability and a method for manufacturing the electronic device.

### 2. Description of the Related Art

Multimedia electronic devices, such as a television, a mobile phone, a tablet computer, a laptop, a navigation system, and a game console, include a display device for displaying an image. The display device displays various images on a display screen to provide information to a user. In general, display devices display information within an allocated screen. Nowadays, flexible electronic devices including a flexible display panel capable of being folded are being developed. The flexible electronic device, unlike a rigid electronic device, may be folded, rolled, or bent. The flexible electronic device having the shape which is changeable in various ways may be portable without being limited by typical screen sizes, thereby improving user convenience. The electronic device includes a display module, and a window disposed on the display module to protect the display module.

### SUMMARY

The disclosure provides an electronic device with improved reliability and a method for manufacturing the electronic device.

An embodiment of the inventive concept provides an electronic device including a display module that displays an image and detects an external input, a window disposed on the display module, defining an opening, and including a first region surrounding the opening and a second region spaced apart from the opening in a plan view, where the first region is disposed between the opening and the second region in the plan view, an anti-fingerprint layer disposed on the second region of the window, an adhesive layer disposed on the first region of the window, and an electronic module disposed on the adhesive layer, overlapping the opening, and at least partially accommodated in the opening.

In an embodiment, the electronic device may further include an upper adhesive layer disposed between the display module and the window.

In an embodiment, the upper adhesive layer may not overlap the opening and overlap the first region and the second region.

In an embodiment, the electronic device may further include a light-blocking pattern which is disposed on a rear surface of the window, does not overlap the opening, and overlaps the first region.

In an embodiment, the light-blocking pattern may overlap at least a portion of the second region.

In an embodiment, a thickness of the adhesive layer may be greater than a thickness of the anti-fingerprint layer.

In an embodiment, the electronic module may be a camera module.

In an embodiment, the electronic module may be disposed on the window and include a first portion having a first width, and a second portion accommodated in the opening and having a second width smaller than the first width.

In an embodiment of the inventive concept, a method for manufacturing an electronic device includes forming a display module, forming a window defining an opening and including a first region surrounding the opening and a second region spaced apart from the opening in a plan view, where the first region is disposed between the opening and the second region in the plan view, forming an anti-fingerprint layer on the first region and the second region of the window, removing a portion of the anti-fingerprint layer formed in a region overlapping the first region, forming an adhesive layer in a region from which the portion of the anti-fingerprint layer is removed, and disposing an electronic module on the adhesive layer.

In an embodiment, the removing the portion of the anti-fingerprint layer may include forming, on the anti-fingerprint layer, a mask defining an opening corresponding to the first region is defined, and plasma-etching the portion of the anti-fingerprint layer overlapping the opening of the mask by the mask.

In an embodiment, the removing the portion of the anti-fingerprint layer may include laser-etching the portion of the anti-fingerprint layer formed in a region overlapping the first region.

In an embodiment, the method may further include, before the forming the anti-fingerprint layer, forming an ink layer on the first region of the window, and the ink layer may include a peelable ink, and the anti-fingerprint layer may cover the ink layer.

In an embodiment, in the removing the portion of the anti-fingerprint layer, the portion of the anti-fingerprint layer may be removed together with the ink layer.

In an embodiment, the method may further include peeling off the ink layer by a water-soluble solution.

In an embodiment, the method may further include peeling off the ink layer by an alkaline solution.

In an embodiment, the method may further include peeling off the ink layer through a physical method.

In an embodiment, a thickness of the adhesive layer may be greater than a thickness of the anti-fingerprint layer.

In an embodiment, the method may further include forming a light-blocking pattern to overlap the first region and at least a portion of the second region.

In an embodiment, in the disposing the electronic module, the electronic module may be disposed to overlap the opening and at least partially accommodated in the opening.

In an embodiment, the electronic module may be a camera module.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a block diagram of an embodiment of an electronic device;

FIG. 2A is a perspective view of an embodiment of an electronic device according to the inventive concept;

FIG. 2B is a perspective view of an embodiment of an electronic device according to the inventive concept;

FIG. 2C is a perspective view of an embodiment of an electronic device according to the inventive concept;;

FIG. 3 is an exploded perspective view of an embodiment of an electronic device according to the inventive concept;

FIG. 4 is a cross-sectional view of an embodiment of a display module according to the inventive concept;

FIG. 5 is an exploded perspective view of an embodiment of some components of an electronic device according to the inventive concept;

FIG. 6 is a cross-sectional view of an embodiment of an electronic device taken along line I-I' of FIG. 2B, according to the inventive concept;

FIG. 7A is a diagram for describing an embodiment of a method for manufacturing an electronic device according to the inventive concept;

FIG. 7B is a diagram for describing an embodiment of a method for manufacturing an electronic device according to the inventive concept;

FIG. 8A is a diagram for describing an embodiment of a method for manufacturing an electronic device according to the inventive concept;

FIG. 8B is a diagram for describing an embodiment of a method for manufacturing an electronic device according to the inventive concept;

FIG. 9A is a diagram for describing za method for manufacturing an electronic device according to the inventive concept;

FIG. 9B is a diagram for describing an embodiment of a method for manufacturing an electronic device according to the inventive concept; and

FIG. 10 is a diagram for describing an embodiment of a method for manufacturing an electronic device according to the inventive concept.

### DETAILED DESCRIPTION

In this specification, it will be understood that when an element (or a region, a layer, a portion, or the like) is referred to as being "on", "connected to" or "coupled to" another element, it may be directly disposed on, connected to, or coupled to the other element, or other elements may be disposed therebetween.

Like reference numerals or symbols refer to like elements throughout. In the drawings, the thickness, ratio, and size of the elements are exaggerated for effectively describing the technical contents. As used herein, the term "and/or" includes any and all combinations of one or more of the associated listed elements.

It will be understood that, although the terms “first”, “second”, etc. may be used herein to describe various elements, the elements are not to be limited by these terms. These terms are only used to distinguish one element, component, region, layer or section from another element, component, region, layer or section. For instance, a first element, component, region, layer or section discussed below could be termed a second element, component, region, layer or section without departing from the scope of the inventive concept. Similarly, a second element, component, region, layer or section could be termed a first element, component, region, layer or section. In this specification, the singular expressions "a", "an" and "the" are intended to include the plural forms as well, unless the context clearly indicates otherwise.

In addition, the terms "below", “under”, "on the lower side", "above", “over”, "on the upper side", or the like may be used to describe the relationships between the elements illustrated in the drawings. These terms are relative concepts and are described on the basis of the directions indicated in the drawings.

It will be further understood that the terms "comprises, includes, has" and/or "comprising, including, having", when used in this specification, specify the presence of stated features, numbers, steps, operations, elements, components or combinations thereof, but do not preclude the possibility of the presence or addition of one or more other features, numbers, steps, operations, elements, components, and/or combinations thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the inventive concept are described with reference to the accompanying drawings.

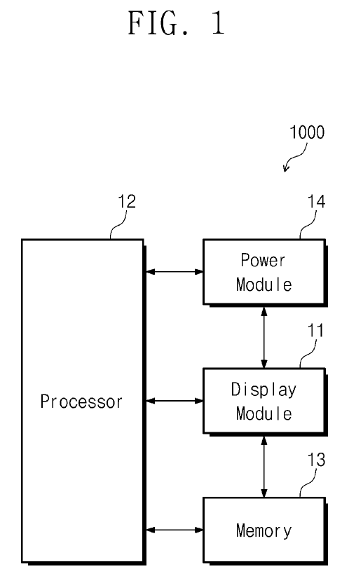

FIG. 1 is a block diagram of an embodiment of an electronic device 1000.

Referring to FIG. 1, the electronic device 1000 in an embodiment may include a display module 11, a processor 12, a memory 13, and a power module 14.

The display module 11 may display an image. The image may include a still image as well as a moving image. The processor 12 may include at least one among a central processing unit (“CPU”), an application processor (“AP”), a graphic processing unit (“GPU”), a communication processor (“CP”), an image signal processor (“ISP”), and a controller. The processor 12 may control an operation of the display module 11.

The memory 13 may store data information desired for an operation of the processor 12 or the display module 11. When the processor 12 executes an application stored in the memory 13, an image data signal and/or an input control signal may be transferred to the display module 11, and the display module 11 may process the received signal and output image information through a display screen.

The power module 14 may include a power supply module, such as a power adaptor or a battery device, and a power conversion module that converts power supplied by the power supply module to generate power desired for an operation of the electronic device 1000.

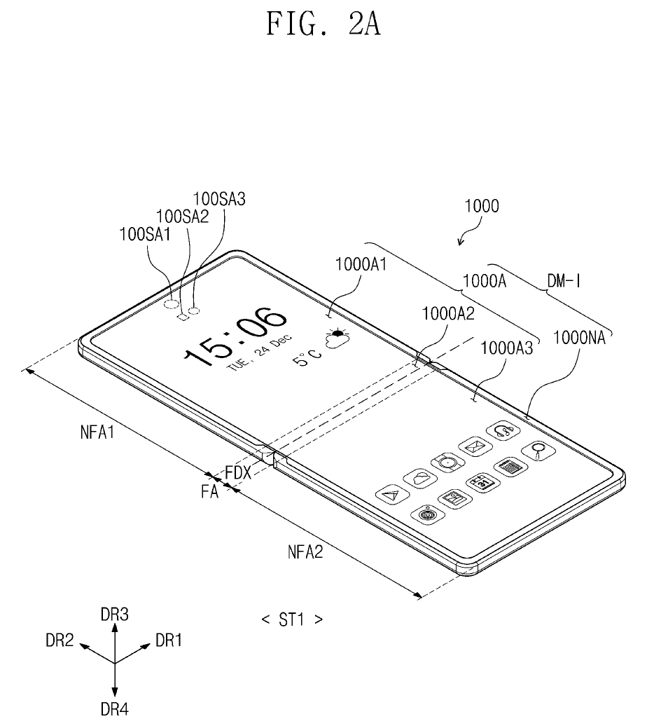

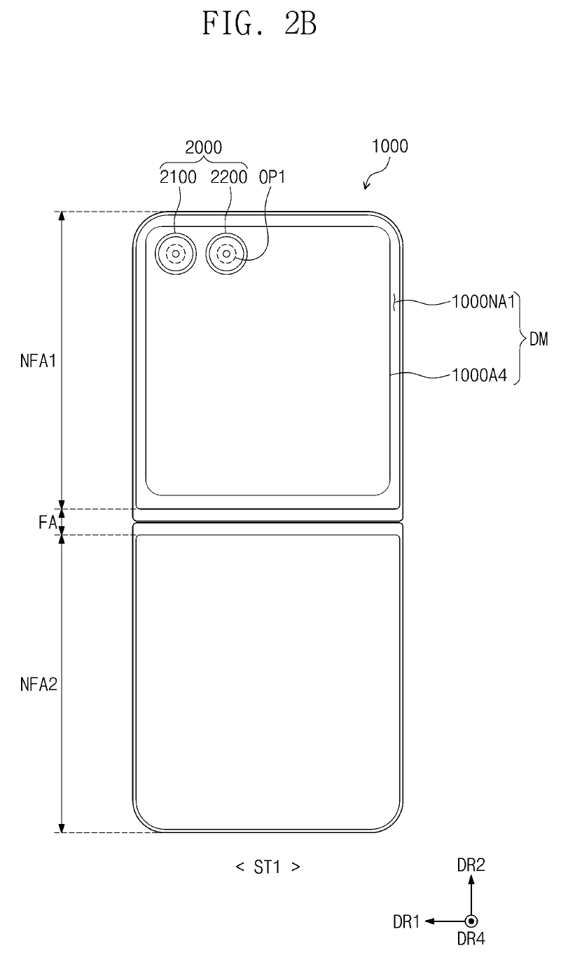

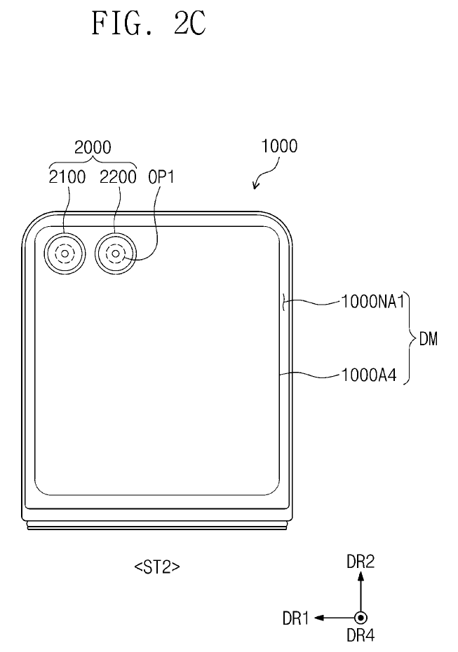

FIG. 2A is a perspective view of an embodiment of the electronic device 1000 according to the inventive concept. FIG. 2B is a perspective view of an embodiment of the electronic device 1000 according to the inventive concept. FIG. 2C is a perspective view of an embodiment of the electronic device 1000 according to the inventive concept.

FIG. 2A illustrates a front surface of the electronic device 1000 in a first state ST1 in which the electronic device 1000 is fully unfolded. FIG. 2B illustrates a rear surface of the electronic device 1000 in the first state ST1 in which the electronic device 1000 is fully unfolded. FIG. 2C illustrates a second state ST2 in which the electronic device 1000 is fully folded.

Referring to FIGS. 2A, 2B and 2C, the electronic device 1000 may be activated in response to an electrical signal. In an embodiment, the electronic device 1000 may be a mobile phone, a tablet computer, a car navigation system, a game console, or a wearable device, for example, but is not limited thereto. In FIG. 2A, the electronic device 1000 is illustrated as a mobile phone as an example.

The electronic device 1000 may include a folding region FA and a plurality of non-folding regions NFA1 and NFA2. The non-folding regions NFA1 and NFA2 may include a first non-folding region NFA1 and a second non-folding region NFA2. The folding region FA may be disposed between the first non-folding region NFA1 and the second non-folding region NFA2. The first non-folding region NFA1, the folding region FA, and the second non-folding region NFA2 may be arranged along an opposite direction of a second direction DR2.

In an embodiment, one folding region FA and two non-folding regions NFA1 and NFA2 are illustrated, but the number of folding region FA and the number of non-folding regions NFA1 and NFA2 is not limited thereto. In an embodiment, the electronic device 1000 may include a plurality of non-folding regions the number of which is more than two, and a plurality of folding regions disposed between the non-folding regions, for example.

The thickness direction of the electronic device 1000 may be parallel to a third direction DR3 and a fourth direction DR4 that intersect a first direction DR1 and the second direction DR2. Accordingly, the front surface (or upper surface) and the rear surface (or lower surface) of each member constituting the electronic device 1000 may be defined on the basis of the third direction DR3 or the fourth direction DR4.

In an embodiment of the inventive concept, the electronic device 1000 may include a first display module DM-I, a second display module DM, and a plurality of electronic modules 2000. The electronic modules 2000 may include a first electronic module 2100 and a second electronic module 2200. The first display module DM-I may be also referred to as an internal display module or a main display module. The second display module DM may be also referred to as an external display module, an auxiliary display module, or a display module.

An active region 1000A and a peripheral region 1000NA next (adjacent) to the active region 1000A may be defined in the first display module DM-I. The first display module DM-I may display an image through the active region 1000A. In the first state ST1 in which the electronic device 1000 is unfolded, the active region 1000A may include a plane defined by the first direction DR1 and the second direction DR2.

The active region 1000A may include a first active region 1000A1, a second active region 1000A2, and a third active region 1000A3. The first active region 1000A1, the second active region 1000A2, and the third active region 1000A3 may be defined on the front surface in the third direction DR3 in the first state ST1 in which the electronic device 1000 is unfolded.

The first active region 1000A1, the second active region 1000A2, and the third active region 1000A3 may be surrounded by the peripheral region 1000NA. The second active region 1000A2 may be bent with respect to a folding axis FDX extending along the first direction DR1. Accordingly, the first active region 1000A1 and the third active region 1000A3 may be defined in the non-folding regions NFA1 and NFA2, and the second active region 1000A2 may be defined in the folding region FA.

A plurality of sensing regions 100SA1, 100SA2, and 100SA3 may be defined in the first display module DM-I. In FIG. 2A, three sensing regions 100SA1, 100SA2, and 100SA3 are illustrated in an embodiment, but the number of sensing regions 100SA1, 100SA2, and 100SA3 is not limited thereto. In an embodiment of the inventive concept, the second sensing region 100SA2 and the third sensing region 100SA3 may be omitted.

The sensing regions 100SA1, 100SA2, and 100SA3 may include a first sensing region 100SA1, a second sensing region 100SA2, and a third sensing region 100SA3. In an embodiment, the first sensing region 100SA1 may overlap a camera module, and the second sensing region 100SA2 and the third sensing region 100SA3 may overlap a proximity illuminance sensor, for example, but the inventive concept is not limited thereto.

Each of the plurality of electronic modules may receive an external input transmitted through the first sensing region 100SA1, the second sensing region 100SA2, and the third sensing region 100SA3, or may provide an output through the first sensing region 100SA1, the second sensing region 100SA2, and the third sensing region 100SA3.

In an embodiment of the inventive concept, the first sensing region 100SA1, the second sensing region 100SA2, and the third sensing region 100SA3 may be included in the active region 1000A. That is, the first sensing region 100SA1, the second sensing region 100SA2, and the third sensing region 100SA3 may display an image. The transmittance of each of the first sensing region 100SA1, the second sensing region 100SA2, and the third sensing region 100SA3 may be higher than the transmittance of a portion of the active region 1000A around the first sensing region 100SA1, the second sensing region 100SA2, and the third sensing region 100SA3. Each of the first sensing region 100SA1, the second sensing region 100SA2, and the third sensing region 100SA3 may be defined as a first region, and the portion of the active region 1000A may be defined as a second region. Accordingly, the transmittance of the first region may be higher than the transmittance of the second region.

In an embodiment of the inventive concept, the first sensing region 100SA1 may be surrounded by the active region 1000A. That is, the first sensing region 100SA1 may not display an image. In this case, the transmittance of the first sensing region 100SA1 may be higher than the transmittance of each of the second sensing region 100SA2 and the third sensing region 100SA3.

In an embodiment of the inventive concept, the region in which the electronic modules are to be disposed may not be necessarily provided in the peripheral region 1000NA around the active region 1000A. As a result, the area proportion of the active region 1000A may be increased as compared to the front surface of the electronic device 1000.

In an embodiment of the inventive concept, a fourth active region 1000A4 and a first peripheral region 1000NA1 next (adjacent) to the fourth active region 1000A4 may be defined in the second display module DM. The fourth active region 1000A4 may be surrounded by the first peripheral region 1000NA1.

The second display module DM may display an image through the fourth active region 1000A4. In the first state ST1 in which the electronic device 1000 is unfolded and in the second state ST2 in which the electronic device 1000 is fully folded, the fourth active region 1000A4 may include a plane defined by the first direction DR1 and the second direction DR2.

The fourth active region 1000A4 may be defined on a portion of the rear surface of the electronic device 1000 in the fourth direction DR4 in the first state ST1 in which the electronic device 1000 is unfolded, and on one surface in the fourth direction DR4 in the second state ST2 in which the electronic device 1000 is fully folded. That is, the fourth active region 1000A4 may be defined on the rear surface of the first non-folding region NFA1. Accordingly, a user may view an image in both the unfolded first state ST1 and the fully folded second state ST2 of the electronic device 1000.

When the electronic device 1000 is folded, the first active region 1000A1 and the third active region 1000A3 may face each other. Therefore, in the fully folded second state ST2, only the fourth active region 1000A4 may be exposed to the outside, and the first active region 1000A1, the second active region 1000A2, and the third active region 1000A3 may not be exposed to the outside.

FIGS. 2A, 2B and 2C, illustrate as an example that the folding axis FDX is parallel to a short axis of the electronic device 1000, but the inventive concept is not limited thereto. In an embodiment, the folding axis FDX may extend along a long axis of the electronic device 1000, e.g., along the direction parallel to the second direction DR2, for example. In this case, the first active region 1000A1, the second active region 1000A2, and the third active region 1000A3 may be sequentially arranged along the first direction DR1.

In an embodiment of the inventive concept, a plurality of first openings OP1 may be defined in the second display module DM. In FIGS. 2B and 2C, two first openings OP1 are illustrated in an embodiment, but the number of first openings OP1 is not limited thereto.

In an embodiment of the inventive concept, one first opening OP1 may overlap the first electronic module 2100, and a remaining (the other) first opening OP1 may overlap the second electronic module 2200. Each of the first electronic module 2100 and the second electronic module 2200 may be attached through the front of the second display module DM. That is, each of the first electronic module 2100 and the second electronic module 2200 may be attached to an upper side of the second display module DM in the fourth direction DR4. In an embodiment, each of the first electronic module 2100 and the second electronic module 2200 may be a camera module.

In an embodiment of the inventive concept, the first openings OP1 may be surrounded by the fourth active region 1000A4. That is, the first openings OP1 may not display an image.

In an embodiment of the inventive concept, the region in which the electronic modules 2000 are to be disposed may not be necessarily provided in the first peripheral region 1000NA1 around the fourth active region 1000A4. As a result, the area proportion of the fourth active region 1000A4 may be increased as compared to the rear surface of the electronic device 1000.

Although FIGS. 2A and 2B illustrate the foldable electronic device 1000 in an embodiment, the application of the inventive concept is not limited to the foldable electronic device 1000. In an embodiment, the inventive concept may also be applied to a rigid electronic device, e.g., an electronic device that does not include the folding region FA, for example.

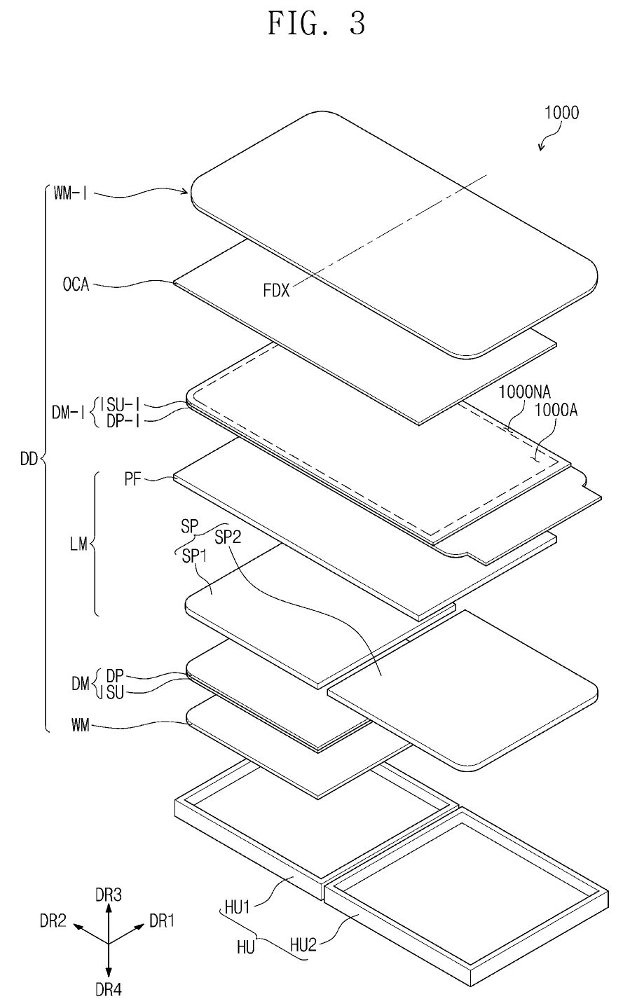

FIG. 3 is an exploded perspective view of an embodiment of the electronic device 1000 according to the inventive concept.

Referring to FIG. 3, the electronic device 1000 may include a display device DD and a housing HU. Although not illustrated, the electronic device 1000 may further include a mechanical structure for controlling a folding operation of the display device DD.

The display device DD in an embodiment of the inventive concept may include a first window WM-I, an upper adhesive layer OCA, the first display module DM-I, a lower module LM, the second display module DM, and a second window WM.

The first window WM-I may be disposed on the first display module DM-I. The first window WM-I may include an optically transparent insulating material. Accordingly, an image generated in the first display module DM-I may be easily recognized by a user through the first window WM-I. Although not illustrated in FIG. 3, the first window WM-I may include a base layer and functional layers disposed on the base layer. The functional layers may include a protective layer, an anti-fingerprint layer, or the like.

The upper adhesive layer OCA may be disposed between the first display module DM-I and the first window WM-I. The upper adhesive layer OCA may have a quadrangular shape, e.g., rectangular shape having short sides extending in the first direction DR1 and long sides extending in the second direction DR2. The first window WM-I and the first display module DM-I may be bonded to each other by the upper adhesive layer OCA.

The first display module DM-I may display an image and detect an external input. The first display module DM-I constitutes a portion of the display device DD, and in particular, an image may be generated by the first display module DM-I. The first display module DM-I may display an image in response to an electrical signal and transmit/receive information about an external input. The first display module DM-I may be defined by the active region 1000A and the peripheral region 1000NA. The active region 1000A may be defined as a region that emits an image provided from the first display module DM-I.

The first display module DM-I may include a first display panel DP-I and a first input sensor ISU-I. The first display panel DP-I in an embodiment of the inventive concept may be a light-emitting display panel and is not particularly limited. In an embodiment, the first display panel DP-I may be an organic light-emitting display panel, an inorganic light-emitting display panel, or a quantum dot light-emitting display panel, for example. The light-emitting layer of the organic light-emitting display panel may include an organic light-emitting material, and the light-emitting layer of the inorganic light-emitting display panel may include an inorganic light-emitting material. The light-emitting layer of the quantum dot light-emitting display panel may include quantum dots, quantum rods, or the like. Hereinafter, the first display panel DP-I is described as an organic light-emitting display panel.

The first display panel DP-I may be a flexible display panel. Accordingly, the first display panel DP-I may be rolled as a whole or folded or unfolded about the folding axis FDX.

The first input sensor ISU-I may be directly disposed on the first display panel DP-I. In an embodiment of the inventive concept, the first input sensor ISU-I may be formed on the first display panel DP-I through a continuous process. That is, when the first input sensor ISU-I is directly disposed on the first display panel DP-I, an adhesive film may not be disposed between the first input sensor ISU-I and the first display panel DP-I. However, the inventive concept is not limited thereto. The adhesive film may be disposed between the first input sensor ISU-I and the first display panel DP-I. In this case, the first input sensor ISU-I and the first display panel DP-I are not manufactured through the continuous process, but the first input sensor ISU-I may be manufactured through a separate process from that for the first display panel DP-I and then be fixed on the upper surface of the first display panel DP-I by the adhesive film.

Although not illustrated, the first display module DM-I may further include an anti-reflection layer. The anti-reflection layer may reduce the reflectance for external light incident from the outside of the display device DD.

The lower module LM may include a support plate SP disposed on the rear surface of the first display module DM-I to support the first display module DM-I, and a protective film PF disposed between the first display module DM-I and the support plate SP.

The support plate SP may include support plates the number of which corresponds to the number of the non-folding regions NFA1 and NFA2 (refer to FIG. 2A). As an embodiment of the inventive concept, the support plate SP may include a first support plate SP1 and a second support plate SP2 disposed spaced apart from the first support plate SP1.

The first and second support plates SP1 and SP2 may be disposed to correspond to the first and second non-folding regions NFA1 and NFA2 (refer to FIG. 2A), respectively. In an embodiment, the first support plate SP1 may be disposed to overlap the first non-folding region NFA1 (refer to FIG. 2A), and the second support plate SP2 may be disposed to overlap the second non-folding region NFA2 (refer to FIG. 2A), for example. Each of the first and second support plates SP1 and SP2 may include a metallic material or a plastic material.

When the electronic device 1000 is in the unfolded first state ST1 (refer to FIG. 2A) as illustrated in FIG. 2A, the first and second support plates SP1 and SP2 may be spaced apart from each other in the second direction DR2. When the electronic device 1000 is in the second state ST2 (refer to FIG. 2C) of being fully folded with respect to the folding axis FDX as illustrated in FIG. 2C, the first and second support plates SP1 and SP2 may be spaced apart from each other in the third direction DR3.

The first and second support plates SP1 and SP2 may be spaced at a distance corresponding to the folding region FA (refer to FIG. 2A). In addition, the first and second support plates SP1 and SP2 may partially overlap the folding region FA (refer to FIG. 2A). That is, the spacing distance between the first and second support plates SP1 and SP2 in the second direction DR2 may be smaller than the width of the folding region FA (refer to FIG. 2A).

Although not illustrated, the support plate SP may further include a connection module for connecting the first and second support plates SP1 and SP2. The connection module may include a hinge module or a multi-joint module.

FIG. 3 illustrates that the support plate SP includes two support plates SP1 and SP2, but the inventive concept is not limited thereto. That is, when a plurality of folding axes FDX are provided, the support plate SP may include a plurality of support plates separated with respect to the plurality of folding axes FDX. In addition, the support plate SP may not be separated into the first and second support plates SP1 and SP2, but may be provided in an integral shape. In this case, a bending part may be provided in the support plate SP corresponding to the folding region FA (refer to FIG. 2A). The bending part may be provided with an opening defined by penetrating the support plate SP or may be provided with a groove recessed from one surface of the support plate SP.

The protective film PF may be disposed between the first display module DM-I and the support plate SP. The protective film PF may be disposed under the first display module DM-I to protect the rear surface of the first display module DM-I. The protective film PF may include a synthetic resin film, and may be, e.g., a polyimide film or a polyethylene terephthalate film. However, this is merely one of embodiments, and the protective film PF is not limited to the above examples.

The second display module DM may be disposed in the fourth direction DR4 under the lower module LM. That is, the rear surface of the second display module DM may face the rear surface of the lower module LM.

The second display module DM may have the same configuration as the first display module DM-I. That is, the second display module DM may display an image and detect an external input.

The second display module DM may include a second display panel DP and a second input sensor ISU. The second display panel DP and the second input sensor ISU may include the same configurations as the first display panel DP-I and the first input sensor ISU-I, respectively.

The second window WM may be disposed in the fourth direction DR4 under the second display module DM. That is, the rear surface of the second window WM may face the front surface of the second display module DM. The second window WM and the first window WM-I may consist of the same material as each other.

Although not illustrated, an upper adhesive layer OCA may be further included between the second display module DM and the second window WM. Hereinafter, the second display module DM is also referred to as a display module DM, and the second window WM is also referred to as a window WM.

The housing HU may accommodate the display device DD. It is illustrated that the housing HU includes a first housing HU1 and a second housing HU2 which are separated from each other, but the inventive concept is not limited thereto. Although not illustrated, the electronic device 1000 may further include a hinge structure for connecting the first housing HU1 and the second housing HU2.

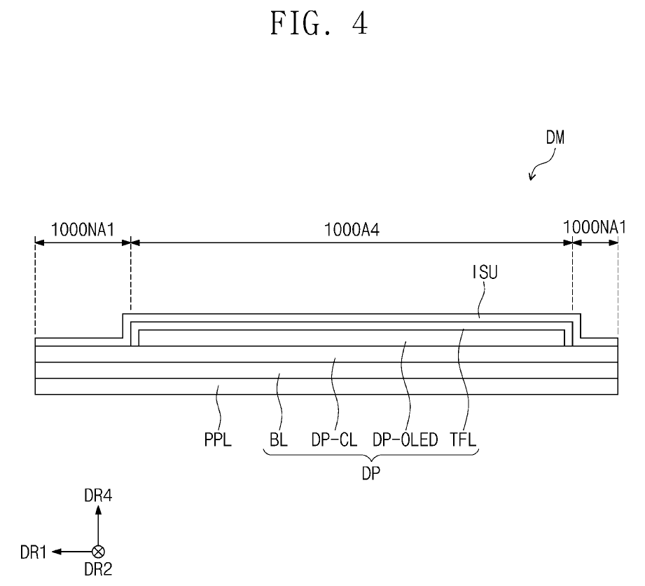

FIG. 4 is a cross-sectional view of an embodiment of a display module DM according to the inventive concept.

Referring to FIG. 4, the display module DM may include a second input sensor (hereinafter also referred to as an input sensor) ISU, a second display panel (hereinafter also referred to as a display panel) DP, and a panel protection layer PPL. The display module DM may include a fourth active region 1000A4 and a first peripheral region 1000NA1.

The display panel DP may include a base layer BL, a circuit element layer DP-CL disposed on the base layer BL, a display element layer DP-OLED, and an upper insulating layer TFL. The input sensor ISU may be disposed on the upper insulating layer TFL.

The base layer BL may include at least one plastic film. The base layer BL may include a flexible substrate, such as a plastic substrate, a glass substrate, a metal substrate, or an organic/inorganic composite material substrate.

The circuit element layer DP-CL may include at least one intermediate insulating layer and a circuit element layer. The intermediate insulating layer may include at least one intermediate inorganic layer and at least one intermediate organic layer. A circuit element may include signal lines, a pixel driving circuit, or the like.

The display element layer DP-OLED may include a plurality of organic light-emitting diodes. The display element layer DP-OLED may further include an organic layer such as a pixel-defining film.

The upper insulating layer TFL may seal the display element layer DP-OLED. The upper insulating layer TFL may be disposed on the display element layer DP-OLED. The upper insulating layer TFL may overlap the fourth active region 1000A4. The upper insulating layer TFL may overlap at least a portion of the first peripheral region 1000NA1. In an embodiment, the upper insulating layer TFL may include a thin-film encapsulation layer. The thin-film encapsulation layer may include a stacked structure of an inorganic layer, an organic layer, and an inorganic layer.

The upper insulating layer TFL may protect the display element layer DP-OLED from foreign substances such as moisture, oxygen, and dust particles. However, the inventive concept is not limited thereto, and the upper insulating layer TFL may further include an additional insulating layer other than the thin-film encapsulation layer. The following description will be made by defining the upper insulating layer TFL as a thin-film encapsulation layer TFL.

In an embodiment of the inventive concept, a sealing substrate may be provided in place of the upper insulating layer TFL. In this case, the sealing substrate faces the base layer BL, and the circuit element layer DP-CL and the display element layer DP-OLED may be disposed between the sealing substrate and the substrate.

The input sensor ISU may be directly disposed on the display panel DP. In this specification, the wording, "an A component is directly disposed on a B component" means that an additional layer is not disposed between the A component and the B component. In this embodiment, the input sensor ISU and the display panel DP may be manufactured through a continuous process. However, the technical idea of the inventive concept is not limited thereto, and the input sensor ISU may be provided as a separate panel and bonded to the display panel DP through an adhesive layer. In an embodiment, the input sensor ISU may be omitted.

The panel protection layer PPL may be disposed under the display panel DP. The panel protection layer PPL may protect a lower portion of the display panel DP. The panel protection layer PPL may include a flexible plastic material. In an embodiment, the panel protection layer PPL may include polyethylene terephthalate (“PET”), for example.

FIG. 4 illustrates a cross-sectional view of an embodiment of the display module DM , and the first display module DM-I illustrated in FIG. 3 may also include the same configuration as the display module DM.

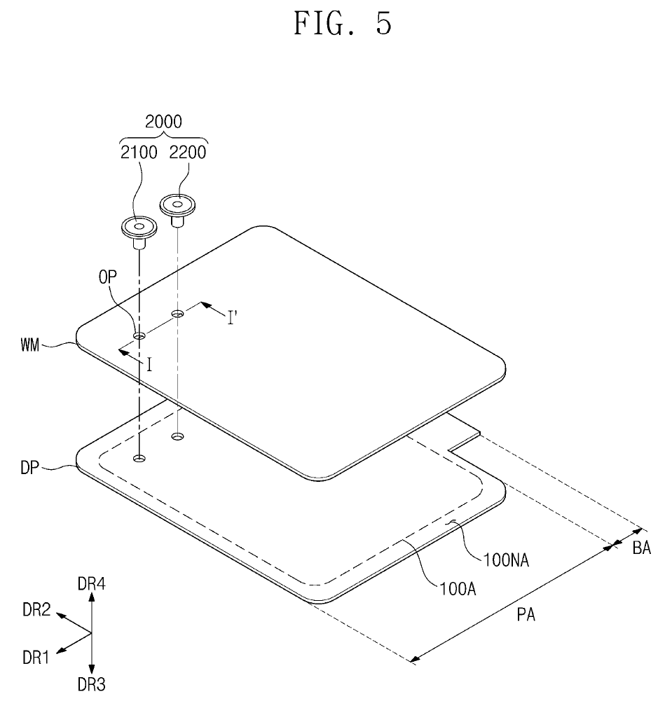

FIG. 5 is an exploded perspective view illustrating an embodiment of some components of the electronic device 1000 (refer to FIG. 2B) according to the inventive concept.

Referring to FIG. 5, the display panel DP, the window WM, and a plurality of electronic modules 2000 are illustrated as an example among components of the electronic device 1000 (refer to FIG. 2B).

A flat part PA and a bending part BA may be defined in the display panel DP. The bending part BA may be a region in which the display panel DP is bent. In addition, although not illustrated, a driving chip may be disposed (e.g., mounted) on the bending part BA of the display panel DP, and an additional circuit film may be attached to the bending part BA of the display panel DP. FIG. 5 illustrates as an example that the bending part BA is next (adjacent) to the flat part PA in the first direction DR1, but the inventive concept is not limited thereto, and the bending part BA may be next (adjacent) to the flat part PA in the second direction DR2.

A display region 100A and a non-display region 100NA next (adjacent) to the display region 100A may be defined in the display panel DP. The display region 100A may be defined on the flat part PA of the display panel DP. The display region 100A of the display panel DP may correspond to the fourth active region 1000A4 of the display module DM illustrated in FIG. 2B, and the non-display region 100NA of the display panel DP may correspond to the peripheral region 1000NA1 of the display module DM illustrated in FIG. 2B. In this specification, the wording, “a region/portion correspond to a region/portion” means that the region/portion overlaps the region/portion and is not limited to having the same area.

In an embodiment of the inventive concept, the electronic modules 2000 may include the first electronic module 2100 and the second electronic module 2200. Each of the first electronic module 2100 and the second electronic module 2200 may overlap an opening OP defined in the window WM. The opening OP defined in the window WM may overlap the first openings OP1 of the display module DM illustrated in FIG. 2B. In an embodiment of the inventive concept, each of the first electronic module 2100 and the second electronic module 2200 may be a camera module.

According to the inventive concept, the first electronic module 2100 and the second electronic module 2200 may be inserted from the front surface of the display panel DP. In an embodiment, a portion of each of the first electronic module 2100 and the second electronic module 2200 may be disposed on the window WM disposed on the display panel DP and may be inserted and coupled from the upper surface of the window WM toward the display panel DP, for example. Accordingly, the first electronic module 2100 and the second electronic module 2200 may be disposed on the window WM so as to protrude at least partially.

Compared to the case in which the electronic modules 2000 are entirely disposed under the window WM, the space, which is desired under the window WM for disposing the electronic modules 2000, may be reduced in the case according to the inventive concept in which the electronic modules 2000 are disposed by being inserted from above the window WM. Accordingly, the overall thickness of the electronic device 1000 (FIG. 2B) may be reduced.

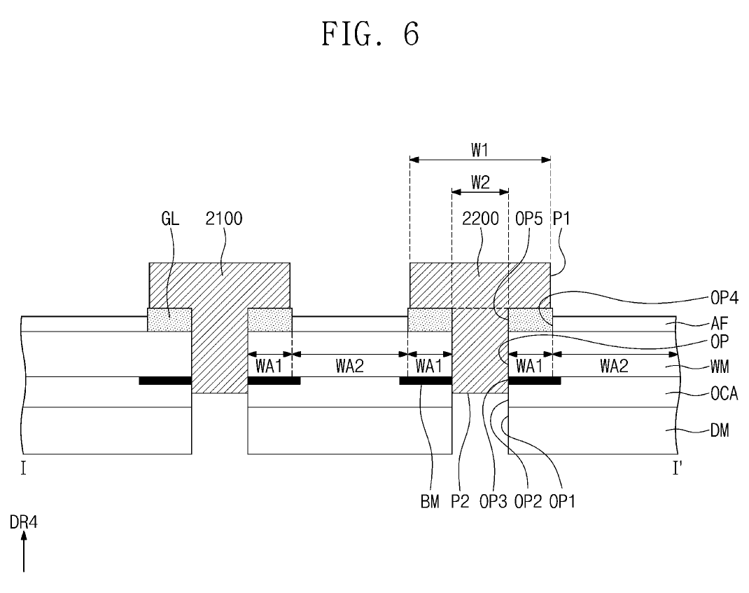

FIG. 6 is a cross-sectional view of an embodiment of some components of the electronic device 1000 (refer to FIG. 2B) taken along line I-I' of FIG. 5 according to the inventive concept.

Referring to FIG. 6, the electronic device 1000 may include the display module DM, the upper adhesive layer OCA, a light-blocking pattern BM, the window WM, an anti-fingerprint layer AF, an adhesive layer GL, the first electronic module 2100, and the second electronic module 2200. Each of the first electronic module 2100 and the second electronic module 2200 may be also referred to as a camera module.

The window WM may be disposed on the upper adhesive layer OCA and the light-blocking pattern BM. The opening OP for accommodating the first electronic module 2100 and the second electronic module 2200 may be defined in the window WM.

In an embodiment of the inventive concept, the opening OP is defined in the window WM, and the window WM may include a first region WA1 surrounding the opening OP and a second region WA2 spaced apart from the opening OP. The first region WA1 may be disposed between the opening OP and a second region WA2.

In an embodiment of the inventive concept, the upper adhesive layer OCA may be disposed between the display module DM and the window WM. The upper adhesive layer OCA and the display module DM may not overlap the opening OP of the window WM and may overlap the first region WA1 of the window WM and the second region WA2 of the window WM. That is, each of the first opening OP1 defined in the display module DM and the second opening OP2 defined in the upper adhesive layer OCA may correspond to the opening OP of the window WM. The upper adhesive layer OCA may bond the window WM and the display module DM.

The light-blocking pattern BM may be disposed on the rear surface of the window WM. The light-blocking pattern BM is a layer having a black color, and in an embodiment, the light-blocking pattern BM may include a black coloring agent. The black coloring agent may include a black dye or a black pigment. The black coloring agent may include carbon black, a metal such as chromium, or an oxide thereof. However, this is an illustrative embodiment, and the material constituting the light-blocking pattern BM is not particularly limited as long as it is a material that absorbs light.

In an embodiment of the inventive concept, the light-blocking pattern BM may not overlap the opening OP of the window WM and may overlap the first region WA1 of the window WM. Additionally, the light-blocking pattern BM may overlap at least a portion of the second region WA2 of the window WM. That is, a third opening OP3 corresponding to the opening OP of the window WM may be defined in the light-blocking pattern BM, and the light-blocking pattern BM may have a ring shape.

In an embodiment of the inventive concept, the anti-fingerprint layer AF may be disposed on the second region WA2 of the window WM. The anti-fingerprint layer AF may not overlap the opening OP of the window WM and the first region WA1. That is, a fourth opening OP4 that is larger than the opening OP of the window WM is defined in the anti-fingerprint layer AF. The fourth opening OP4 of the anti-fingerprint layer AF may overlap the opening OP of the window WM and the first region WA1. The anti-fingerprint layer AF may be an anti-contamination layer that prevents contamination such as user hand marks (e.g., fingerprint marks).

In an embodiment of the inventive concept, the adhesive layer GL may be disposed on the first region WA1 of the window WM. The adhesive layer GL may not overlap the opening OP and the second region WA2 of the window WM. That is, a fifth opening OP5 corresponding to the opening OP of the window WM is defined in the adhesive layer GL, and the adhesive layer GL may have a donut shape. In an embodiment, the adhesive layer GL may include an epoxy resin or an acrylate resin.

In an embodiment of the inventive concept, the thickness of the adhesive layer GL may be greater than the thickness of the anti-fingerprint layer AF. That is, the width of the adhesive layer GL in the fourth direction DR4 may be larger than the width of the anti-fingerprint layer AF in the fourth direction DR4.

In an embodiment of the inventive concept, a portion of each of the first electronic module 2100 and the second electronic module 2200 may be disposed on the adhesive layer GL. The first electronic module 2100 and the second electronic module 2200 may overlap the openings OP of the window WM in a one-to-one correspondence, respectively. Additionally, at least a portion of each of the first electronic module 2100 and the second electronic module 2200 may be accommodated within the openings OP of the window WM.

In an embodiment of the inventive concept, each of the first electronic module 2100 and the second electronic module 2200 may include a first portion P1 disposed on the window WM and having a first width W1, and a second portion P2 accommodated in an opening OP of the window WM and having a second width W2 smaller than the first width W1.

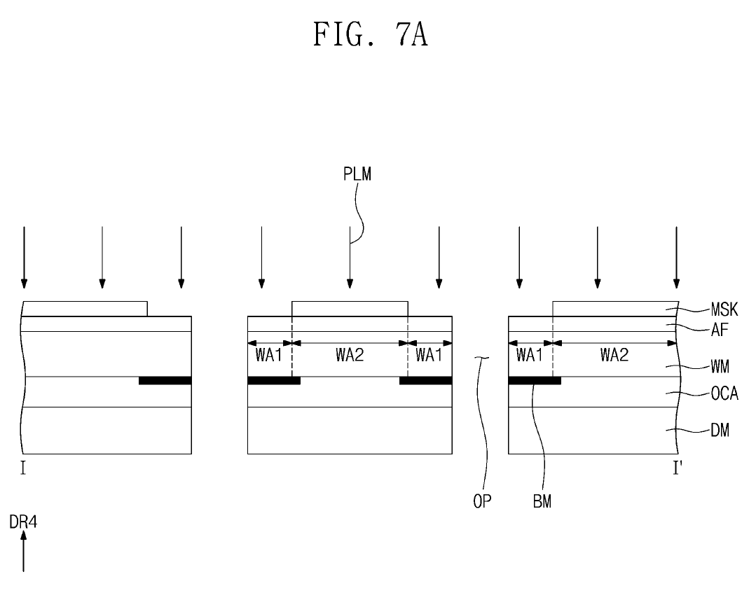

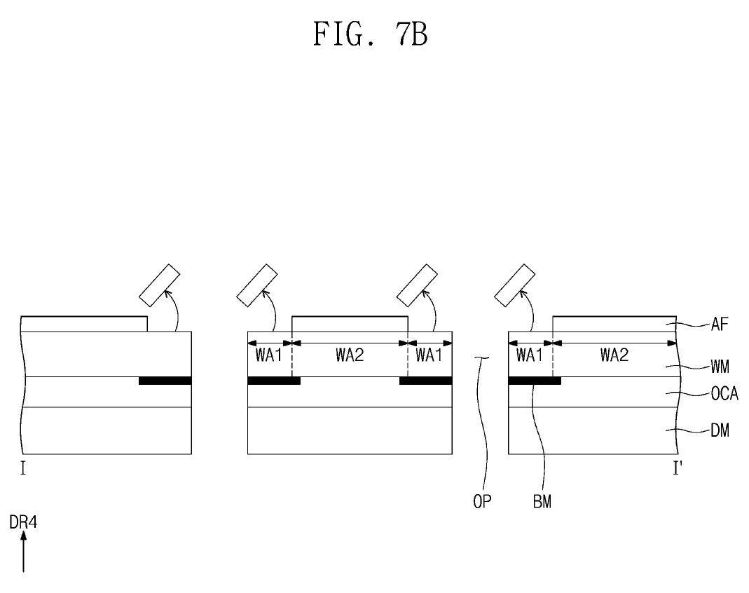

FIG. 7A is a diagram for describing an embodiment of a method for manufacturing an electronic device according to the inventive concept. FIG. 7B is a diagram for describing an embodiment of a method for manufacturing an electronic device according to the inventive concept.

Referring to FIGS. 6, 7A and 7B, the method for manufacturing the electronic device may include an operation of forming a display module DM, an operation of forming a window WM that includes a first region WA1 defining an opening OP therein and surrounding the opening OP, and a second region WA2 spaced apart from the opening OP, an operation of forming a light-blocking pattern BM on the rear surface of the window WM, an operation of bonding the display module DM and the window WM using an upper adhesive layer OCA, an operation of forming an anti-fingerprint layer AF on the first region WA1 and the second region WA2 of the window WM, and an operation of removing a portion of the anti-fingerprint layer AF in a region overlapping the first region WA1. The first region WA1 may be disposed between the opening OP and a second region WA2. The above-described operations are not necessarily performed in the listed order, and the order of the operations may be variously changed.

A first opening OP1 defined in the display module DM, a second opening OP2 defined in the upper adhesive layer OCA, and the opening OP defined in the window WM may overlap each other. The first opening OP1, the second opening OP2, and the opening OP may be formed simultaneously in a state in which the display module DM, the upper adhesive layer OCA, and the window WM are bonded. In an alternative embodiment, the first opening OP1, the second opening OP2, and the opening OP may be respectively formed before bonding of the display module DM, the upper adhesive layer OCA, and the window WM, and then may be aligned to overlap each other.

In an embodiment of the inventive concept, the light-blocking pattern BM may be formed to overlap the first region WA1 of the window WM. Additionally, the light-blocking pattern BM may be formed to overlap at least a portion of the second region WA2 of the window WM. The third opening OP3 defined in the light-blocking pattern BM may overlap the first opening OP1 of the display module DM, the second opening OP2 of the upper adhesive layer OCA, and the opening OP of the window WM.

In the operation of forming the anti-fingerprint layer AF, the anti-fingerprint layer AF may be formed so as to not overlap the opening OP of the window WM and to overlap the first region WA1 of the window WM and the second region WA2 of the window.

In an embodiment of the inventive concept, the operation of removing a portion of the anti-fingerprint layer AF may include an operation of forming, on the anti-fingerprint layer AF, a mask MSK in which an opening corresponding to the first region WA1 is defined, and an operation of plasma-etching a portion of the anti-fingerprint layer AF overlapping the opening of the mask MSK by plasma PLM and the mask MSK.

The plasma-etching operation may be an operation of removing a portion of the anti-fingerprint layer AF in the region overlapping the first region WA1 by plasma PLM formed by ionizing a reactive gas. In an embodiment, the plasma-etching may include a chemical etching according to reactive ions, a physical etching by ion-sputtering, and a hybrid etching that utilizes both the chemical etching and the physical etching, for example.

According to the inventive concept, a portion of the anti-fingerprint layer AF may be removed in a region that does not overlap the mask MSK, that is, in a region that overlaps the first region WA1, by plasma-etching.

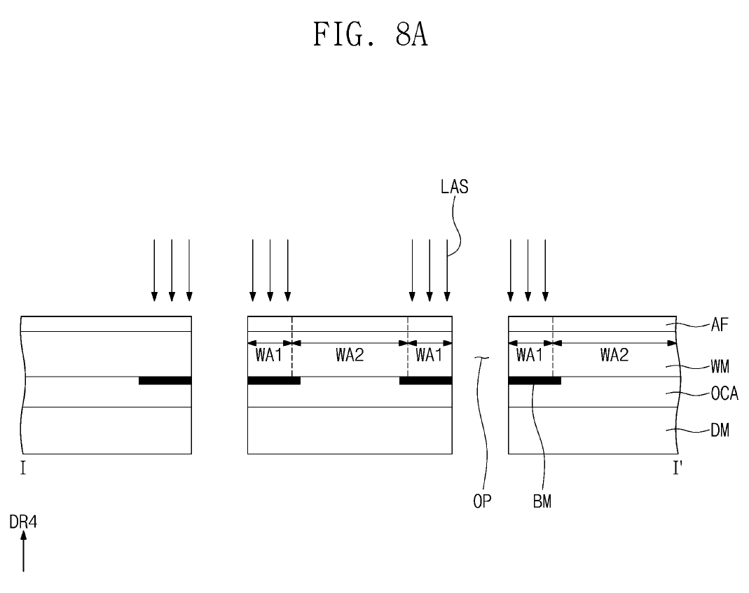

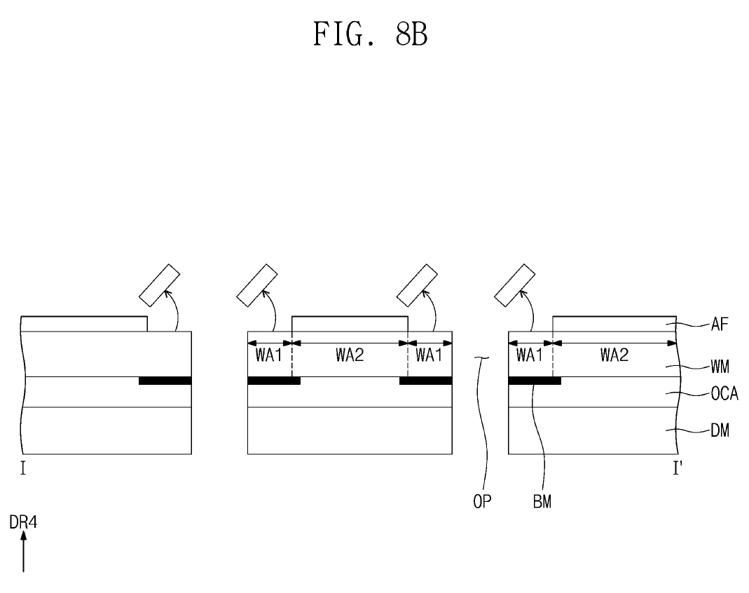

FIG. 8A is a diagram for describing an embodiment of a method for manufacturing an electronic device according to the inventive concept. FIG. 8B is a diagram for describing an embodiment of a method for manufacturing an electronic device according to the inventive concept. Among the components illustrated in FIGS. 8A and 8B, the same components as those illustrated in FIGS. 7A and 7B are denoted as the same reference numerals or symbols, and the descriptions thereof are omitted.

Referring to FIGS. 8A and 8B, the operation of removing a portion of the anti-fingerprint layer AF may include an operation of laser-etching a portion of the anti-fingerprint layer AF in the region overlapping the first region WA1.

The laser-etching operation may be an operation of precisely removing, by an intense light (e.g., a high-powered laser LAS), a portion of the anti-fingerprint layer AF in a predetermined region, that is, the region overlapping the first region WA1. Since the laser-etching is a non-contact etching, a pattern may be formed with relatively high precision while minimizing physical damages. According to the inventive concept, a portion of the anti-fingerprint layer AF in the region overlapping the first region WA1 may be removed by the laser-etching.

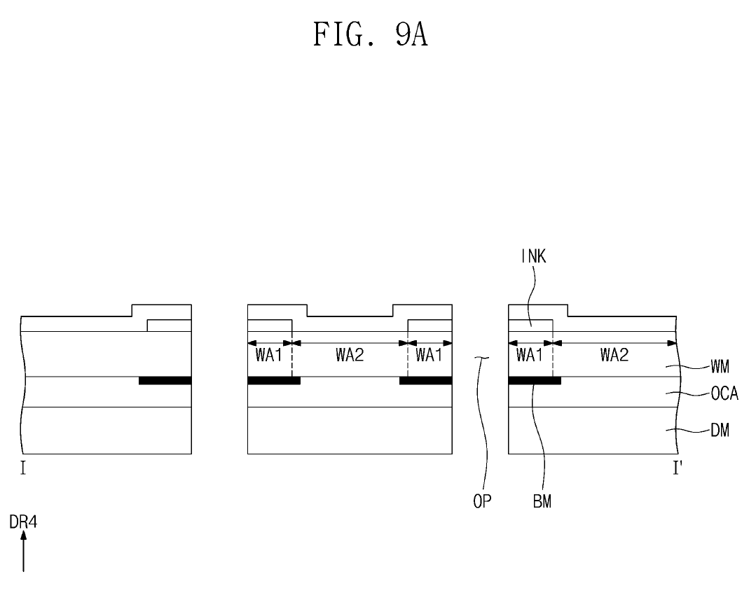

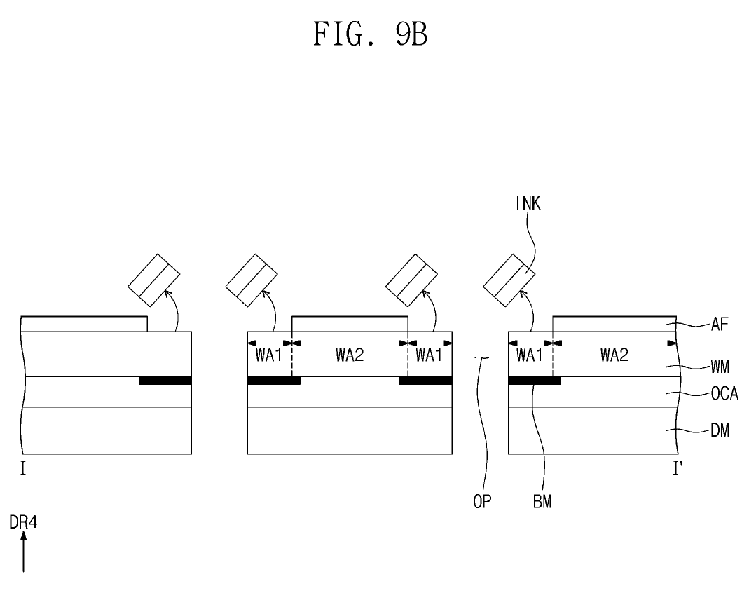

FIG. 9A is a diagram for describing an embodiment of a method for manufacturing an electronic device according to the inventive concept. FIG. 9B is a diagram for describing an embodiment of a method for manufacturing an electronic device according to the inventive concept. Among the components illustrated in FIGS. 9A and 9B, the same components as those illustrated in FIGS. 7A and 7B are denoted as the same reference numerals or symbols, and the descriptions thereof are omitted.

Referring to FIGS. 9A and 9B, the method for manufacturing an electronic device may further include an operation of forming an ink layer INK on the first region WA1 of the window WM before forming the anti-fingerprint layer AF. Accordingly, the anti-fingerprint layer AF may be formed on the window WM while covering the ink layer INK.

In an embodiment of the inventive concept, the ink layer INK may include peelable ink. Accordingly, in a process of removing the ink layer INK, a portion of the anti-fingerprint layer AF formed on the ink layer INK may be removed together.

In an embodiment of the inventive concept, the operation of removing a portion of the anti-fingerprint layer AF may include an operation of peeling off an ink layer INK disposed in the region overlapping the first region WA1. The ink layer INK may be peeled off chemically or physically. In an embodiment, when the ink layer INK includes water-soluble ink, the ink layer INK may be peeled off by being dissolved by a water-soluble solution, for example. In an alternative embodiment, when the ink layer INK includes alkaline ink, the ink layer INK may be peeled off by being dissolved by an alkaline solution. Additionally, in an embodiment, since the ink layer INK includes ink that is easy to be peeled off, the ink layer INK may be peeled off through a physical method of controlling temperature or applying physical pressure to the ink layer INK.

In an embodiment of the inventive concept, by chemically or physically removing the ink layer INK disposed in the region overlapping the first region WA1, a portion of the anti-fingerprint layer AF disposed on the ink layer INK may also be removed together.

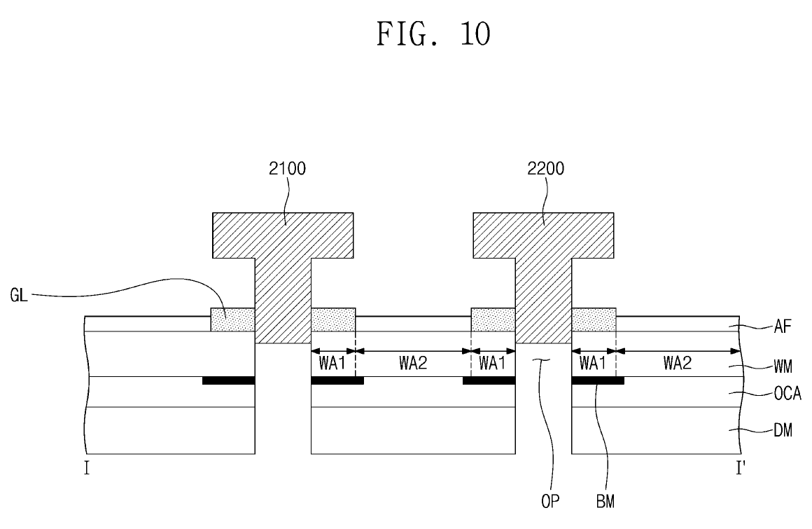

FIG. 10 is a diagram for describing an embodiment of a method for manufacturing an electronic device according to the inventive concept. Among the components illustrated in FIG. 10, the same components as those illustrated in FIGS. 7A and 7B are denoted as the same reference numerals or symbols, and the descriptions thereof are omitted.

Referring to FIG. 10, the method for manufacturing an electronic device may further include an operation of forming the adhesive layer GL in a region in which a portion of the anti-fingerprint layer AF has been removed, and an operation of disposing the first electronic module 2100 and the second electronic module 2200 on the adhesive layer GL.

In the operation of forming the adhesive layer GL, the adhesive layer GL may be formed on a region in which a portion of the anti-fingerprint layer AF has been removed, that is, on the first region WA1 of the window WM.

In an embodiment of the inventive concept, a portion of the first electronic module 2100 and the second electronic module 2200 may be disposed on the adhesive layer GL. In an operation of disposing the first electronic module 2100 and the second electronic module 2200, the first electronic module 2100 and the second electronic module 2200 may be disposed so as to overlap the opening OP of the window WM and to be at least partially accommodated in the opening OP.

In an embodiment of the inventive concept, the adhesive layer GL is disposed between the first electronic module 2100 and the second electronic module 2200 and the window WM, and the adhesive layer GL may bond the first electronic module 2100 and the second electronic module 2200 and the window WM.

Unlike the inventive concept, when the adhesive layer GL is formed on the anti-fingerprint layer AF, the adhesive strength of the adhesive layer GL may be weakened by the anti-fingerprint layer AF which is chemically stable and has a smooth surface. However, according to the inventive concept, since the adhesive layer GL is formed in the region in which the anti-fingerprint layer AF is removed, the adhesive strength between the first electronic module 2100 and the second electronic module 2200 and the window WM may be improved. Accordingly, the reliability of the electronic device 1000 (refer to FIG. 2B) may be improved.

Additionally, according to the inventive concept, the first electronic module 2100 and the second electronic module 2200 may be attached on the front surface of the display module DM in the fourth direction DR4. That is, the first electronic module 2100 and the second electronic module 2200 may be attached on the front surface of the window WM disposed on the display module DM. In this case, compared to the case in which first electronic module 2100 and the second electronic module 2200 are entirely disposed under the window WM, when the first electronic module 2100 and the second electronic module 2200 are disposed by being inserted from the upper portion of the window WM, the space desired to be secured under the window WM for disposing the first electronic module 2100 and the second electronic module 2200 may be reduced. Accordingly, the thickness of the electronic device 1000 (refer to FIG. 2B) may be reduced.

According to the description above, a window may be disposed on a display module, and an anti-fingerprint layer may be disposed on the window. Additionally, an adhesive layer may be disposed to attach a plurality of electronic modules to a region in which an anti-fingerprint layer has been removed. Since the adhesive layer is disposed in the region in which the anti-fingerprint layer has been removed, the adhesive strength between the electronic modules and the window may be improved. Accordingly, the reliability of the electronic device may be improved.

Additionally, the electronic modules may be attached to the front surface of the window and may be inserted into an opening defined in the window. In this case, compared to when the entirety of the electronic modules are disposed under the window, when the electronic modules are disposed by being inserted from the upper portion of the window, the space desired to be secured under the window for disposing the electronic modules may be reduced. Accordingly, the overall thickness of the electronic device may be reduced.

In the above, description has been made with reference to embodiments of the inventive concept, but those skilled or of ordinary skill in the art may understand that various modifications and changes may be made to the inventive concept insofar as such modifications and changes do not depart from the spirit and technical scope of the inventive concept set forth in the claims to be described later.

Therefore, the technical scope of the inventive concept is not to be limited to the contents stated in the detailed description of the specification, but should be determined by the claims.

What is claimed is:

1. An electronic device comprising:
a display module configured to display an image and detect an external input;
a window which is disposed on the display module and in which an opening is defined, the window including:
a first region surrounding the opening; and
a second region spaced apart from the opening in a plan view;
an anti-fingerprint layer disposed on the second region of the window;
an adhesive layer disposed on the first region of the window; and
an electronic module disposed on the adhesive layer, overlapping the opening, and at least partially accommodated in the opening,
wherein the first region is disposed between the opening and the second region in the plan view.

2. The electronic device of claim 1, further comprising an upper adhesive layer disposed between the display module and the window.

3. The electronic device of claim 2, wherein the upper adhesive layer does not overlap the opening and overlaps the first region and the second region.

4. The electronic device of claim 1, further comprising a light-blocking pattern which is disposed on a rear surface of the window, does not overlap the opening, and overlaps the first region.

5. The electronic device of claim 4, wherein the light-blocking pattern overlaps at least a portion of the second region.

6. The electronic device of claim 1, wherein a thickness of the adhesive layer is greater than a thickness of the anti-fingerprint layer.

7. The electronic device of claim 1, wherein the electronic module is a camera module.

8. The electronic device of claim 1, wherein the electronic module is disposed on the window and includes a first portion having a first width, and a second portion accommodated in the opening and having a second width smaller than the first width.

9. A method for manufacturing an electronic device, the method comprising:
forming a display module;
forming a window in which an opening is defined, the window including a first region surrounding the opening and a second region spaced apart from the opening in a plan view;
forming an anti-fingerprint layer on the first region and the second region of the window;
removing a portion of the anti-fingerprint layer formed in a region overlapping the first region;
forming an adhesive layer in a region from which the portion of the anti-fingerprint layer is removed; and
disposing an electronic module on the adhesive layer,
wherein the first region is disposed between the opening and the second region in the plan view.

10. The method of claim 9, wherein the removing the portion of the anti-fingerprint layer comprises:
forming, on the anti-fingerprint layer, a mask in which an opening corresponding to the first region is defined; and
plasma-etching the portion of the anti-fingerprint layer overlapping the opening of the mask by the mask.

11. The method of claim 9, wherein the removing the portion of the anti-fingerprint layer comprises laser-etching the portion of the anti-fingerprint layer formed in a region overlapping the first region.

12. The method of claim 9, further comprising, before the forming the anti-fingerprint layer, forming an ink layer on the first region of the window,
wherein the ink layer includes a peelable ink, and the anti-fingerprint layer covers the ink layer.

13. The method of claim 12, wherein in the removing the portion of the anti-fingerprint layer, the portion of the anti-fingerprint layer is removed together with the ink layer.

14. The method of claim 13, further comprising peeling off the ink layer by a water-soluble solution.

15. The method of claim 13, further comprising peeling off the ink layer by an alkaline solution.

16. The method of claim 13, further comprising peeling off the ink layer through a physical method.

17. The method of claim 9, wherein a thickness of the adhesive layer is greater than a thickness of the anti-fingerprint layer.

18. The method of claim 9, further comprising forming a light-blocking pattern to overlap the first region and at least a portion of the second region.

19. The method of claim 9, wherein, in the disposing the electronic module, the electronic module is disposed to overlap the opening and at least partially accommodated in the opening.

20. The method of claim 9, wherein the electronic module is a camera module.
